(19) United States
(12) Patent Application Publication
(10) Pub. No.: US 2008/0067539 A1
(43) Pub. Date: Mar. 20, 2008

(54) Semiconductor light emitting element and method of making the same

(75) Inventor: Yukio Shakuda, Kyoto (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 11/897,237

(22) Filed: Aug. 29, 2007

(30) Foreign Application Priority Data
Aug. 29, 2006 (JP) 2006-232030

(51) Int. Cl. H01L 33/00

(52) U.S. Cl. 257/99; 257/E33.065; 257/E33.023

(57) ABSTRACT

A semiconductor light emitting element includes a substrate with upper and lower surfaces, a first nitride semiconductor layer on the upper surface of the substrate, a second nitride semiconductor layer arranged farther from the substrate than the first nitride semiconductor layer is, an active layer between the first and second nitride semiconductor layers, and a metal electrode on the second nitride semiconductor layer. As viewed in the thickness direction of the substrate, in which the upper and the lower surfaces are spaced from each other, an active layer area provided with the active layer is smaller than a semiconductor layer area provided with the second nitride semiconductor layer. An electrode area provided with the metal electrode overlaps with at least part of a residual area which is equal to the semiconductor layer area except the active layer area.

### BACKGROUND OF THE INVENTION

1. Field of the Invention

The present invention relates to a semiconductor light emitting element which includes a semiconductor layer containing GaN, and further to a method of making such a semiconductor light emitting element.

2. Description of the Related Art

An example of conventional semiconductor light emitting element is disclosed in JP-A-2006-13475. As shown in FIG. 9 of the present application, the conventional semiconductor light emitting element (generally indicated by a reference character X) includes a substrate 91, a buffer layer 911, an n-GaN layer 92, an active layer 93, a translucent p-GaN layer 94, a p-electrode 951, a transparent electrode 952, and an n-electrode 953. The active layer 93 has a multiple quantum well (MQW) structure of semiconductor layers containing InGaN with different relative proportions of In. In the semiconductor light emitting element X, the p-electrode 951 is electrically connected to an anode of an external power source via a metal wire, and the n-electrode 953 is electrically connected to a cathode of the external power source, for light emission from the active layer 93. The light emitted from the active layer 93 passes through the p-GaN layer 94 and the transparent electrode 952, and travels upwardly.

In manufacturing the semiconductor light emitting element X, it is required to prevent the transparent electrode 952 from receiving damage during the bonding of a metal wire to the p-electrode 951. For this, the p-electrode 951 is formed to have a relatively large thickness. However, when the p-electrode 951 has a large thickness, part of light emitted from the active layer 93 is blocked by the p-electrode 951. In this case, since the light emitted from a portion of the active layer 93 provided below the p-electrode 951 does not go outside, the electrical current applied to this portion is wasted, and the light-emitting efficiency of the semiconductor light emitting element is lowered.

### SUMMARY OF THE INVENTION

The present invention has been proposed under the above-described circumstances. It is therefore an object of the present invention to provide a semiconductor light emitting element for reducing power consumption.

According to a first aspect of the present invention, there is provided a semiconductor light emitting element comprising: a substrate having an upper surface and a lower surface; a first nitride semiconductor layer supported by the upper surface of the substrate; a second nitride semiconductor layer arranged farther from the substrate than the first nitride semiconductor layer is; an active layer provided between the first and second nitride semiconductor layers; and a metal electrode provided on the second nitride semiconductor layer. As viewed in a direction of thickness of the substrate in which the upper surface and the lower surface are spaced from each other, the area in which the active layer is provided is defined as an “active layer area”, and similarly, the area in which the second nitride semiconductor layer is provided is defined as a ″semiconductor layer area, and the area in which the metal electrode is provided is defined as an “electrode area. In the present invention, the active layer area is smaller than the semiconductor layer area, and the electrode area overlaps with at least part of the “residual area” which corresponds to the semiconductor layer area except the active layer area.

Preferably, the electrode area may entirely overlap with the residual area.

According to second aspect of the present invention, there is provided with a method of making a semiconductor light emitting element. The method comprises the steps of: forming a first nitride semiconductor layer on a substrate; forming an active layer on the first nitride semiconductor layer; forming a second nitride semiconductor layer on the active layer; processing the first nitride semiconductor layer, the second nitride semiconductor layer and the active layer into a form defined by a surface upright in the thickness direction of the substrate; and subjecting only the active layer to etching for making the active layer narrower than the second nitride semiconductor layer.

Preferably, the etching of the active layer may be performed by wet etching that comprises irradiation of light having a predetermined wavelength that causes excitement in the active layer but no excitement in the first and the second nitride semiconductor layers.

Other features and advantages will be apparent from the following description of the embodiments with reference to the accompanying drawings.

### BRIEF DESCRIPTION OF THE DRAWINGS

FIG. 1 is a sectional view illustrating a semiconductor light emitting element according to a first embodiment of the present invention.

FIG. 2 is a view illustrating a forming step of layers of the semiconductor light emitting element according to the first embodiment.

FIG. 3 is a view illustrating a removing step of a part of the layers shown in FIG. 2.

FIG. 4 is a view illustrating a removing step of a part of an active layer.

FIG. 5 is a view illustrating a forming step of electrodes.

FIG. 6 is a view illustrating a forming step of an insulating layer.

FIG. 7 is a sectional view illustrating a semiconductor light emitting element according to a second embodiment of the present invention.

FIG. 8 is a sectional view illustrating a semiconductor light emitting element according to a third embodiment of the present invention.

FIG. 9 is a sectional view illustrating an example of a conventional semiconductor light emitting element.

### DESCRIPTION OF THE PREFERRED EMBODIMENTS

Preferred embodiments of the present invention will be described below with reference to the accompanying drawings.

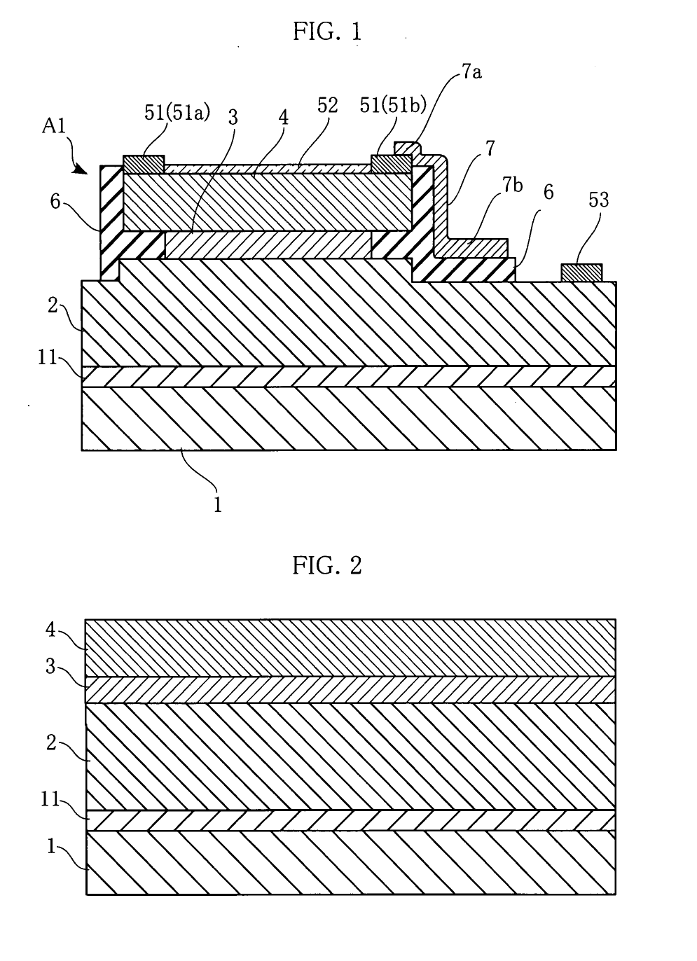

FIG. 1 illustrates a semiconductor light emitting element according to a first embodiment of the present invention. The semiconductor light emitting element A1 includes a substrate 1, a buffer layer 11, an n-GaN layer (first nitride semiconductor layer) 2, an active layer 3, a p-GaN layer (second nitride semiconductor layer) 4, a p-electrode 51, a transparent electrode 52, an n-electrode 53, an insulating layer 6, and a metal layer 7. The semiconductor light emitting element A1 is especially suitable for emitting blue light or green light.

The substrate 1 is made of sapphire, for example. In the present embodiment, the substrate 1 has a thickness (i.e. the distance between the upper surface and the lower surface) of about 300-500 μm, for example. The buffer layer 11 is formed on the upper surface of the substrate 1. The buffer layer 11, made of e.g. A1N, GaN or A1GaN, serves to relieve lattice strain between the substrate 1 and the N-GaN layer 2.

The n-GaN layer 2 is an n-type semiconductor layer made of GaN doped with Si. In the present embodiment, the n-GaN layer 2 has a thickness of about 3-6 μm. The n-GaN layer 2 has a greater length, as viewed in the lateral direction of the FIG., than the active layer 3 and the p-GaN layer 4 laminated on the n-GaN layer, with the n-electrode 53 provided on a portion extending to the right side. The n-GaN layer 2 also has a relatively thick, raised portion on which the active layer 3 is laminated.

The active layer 3 has an MQW structure containing InGaN, and emits light by the recombination of electrons and holes. The active layer 3 has a thickness of about 50-150nm, for example. The active layer 3 includes a plurality of InGaN layers (well layers) and a plurality of GaN layers (barrier layers) laminated alternatively. The number of the InGaN layers is 3 to 7, for example. Similarly, the number of the GaN layers is 3 to 7, for example. The active layer 3 has a length shorter than that of the p-GaN layer 4. Thus, as seen in the thickness direction of the substrate 1, the area in which the active layer 3 is formed (“active layer area”) is smaller than the area in which the p-GaN layer 4 is formed (“semiconductor layer area”).

The p-GaN layer 4 is provided on the upper surface of the active layer 3. The p-GaN layer 4 is a p-type semiconductor layer made of GaN doped with Mg. In the present embodiment, the p-GaN layer 4 has a thickness of about 100-1500 nm. The p-electrode 51 and the transparent electrode 52 are provided on the p-GaN layer 4.

The p-electrode 51 includes two conductive elements, i.e. a first element 51a and a second element 51b. The first element 51a is provided at the left end of the p-GaN layer 4, and the second element 51b is provided at the right end of the p-GaN layer 4. The second element 51b is electrically connected to the metal layer 7. Between the first and second elements 51a, 51b, the transparent electrode 52 is provided. The active layer 3 is not present immediately below the p-electrode 51 (i.e. the first and second elements 51a, 51b), but provided immediately below the transparent electrode 52. Thus, as seen in the thickness direction of the substrate 1, the area in which the p-electrode 51 is provided (“electrode area”) does not overlap with the active layer area. In other words, when a “residual area” is defined as the part of the semiconductor layer area that does not overlap with the active layer area, the entire electrode area is arranged to overlap with the residual area.

The transparent electrode 52 may be a thin film, with a thickness of about 1-20 nm, made of a highly conductive metal such as Au, for example, or may be made of e.g. indium oxide tin (ITO). The transparent electrode 52 partly covers the upper surface of the p-GaN layer 4. With such structure, the transparent electrode 52 allows passage of blue light or green light emitted from the active layer 3, and applies uniform electrical current across the p-GaN layer 4.

The insulating layer 6 is made of SiO₂, for example, and covers the side surfaces of the active layer 3 and the p-GaN layer 4. Further, as shown in FIG. 1, the insulating layer 6 partly covers the upper surface of the n-GaN layer 2, and is spaced from the n-electrode 53. In addition to the original insulating function, the insulating layer 6 also has a function to protect the p-GaN layer 4 from mechanical damage. Specifically, since the p-GaN layer 4 is larger than the active layer 3, part of the p-GaN layer 4 is not supported by the active layer 3. Thus, the p-GaN layer 4 would be damaged by an external force without taking any countermeasures. As illustrated, the insulating layer 6 is inserted between the p-GaN layer 4 and the n-GaN layer 2, whereby the p-GaN layer 4 is protected from mechanical breakage.

The metal layer 7 is made of a highly conductive metal and provided on the insulating layer 6. The metal layer 7 includes an upper end 7a electrically connected to the p-electrode 51 (the second element 51b) The metal layer 7 also includes a lower end 7b which is provided on the horizontal portion of the insulating layer 6 (directly overlapping with the n-GaN layer 2), and extends horizontally. In the present embodiment, a metal wire is bonded to the lower end 7b of the metal layer 7 for electrical connection with an anode of an external power source. A cathode of the external power source is connected to the n-electrode 53 via a metal wire.

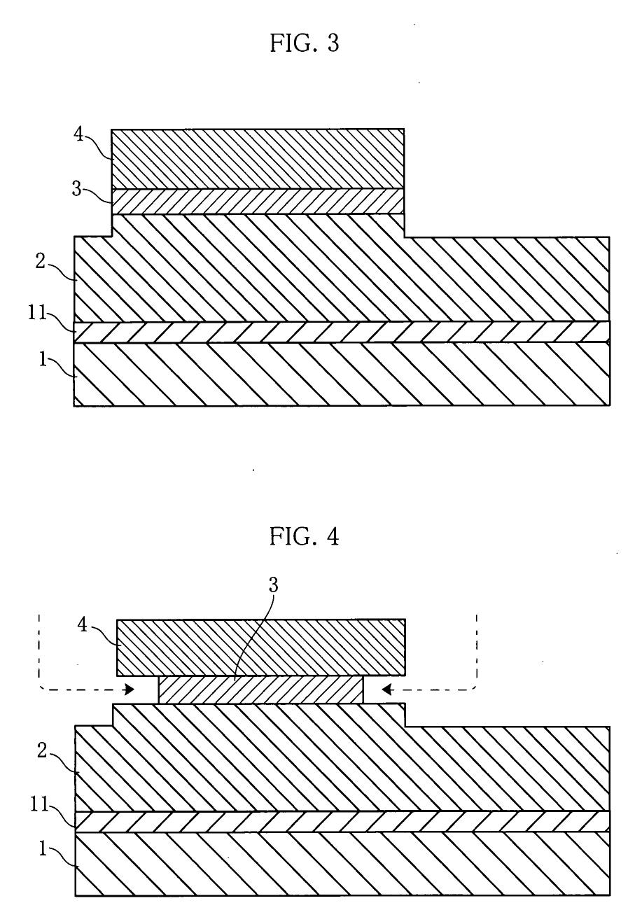

Next, a method of making the semiconductor light emitting element A1 is described with reference to FIGS. 2-6.

First, as shown in FIG. 2, the buffer layer 11, the n-GaN layer 2, the active layer 3, and the p-GaN layer 4 are successively laminated on the substrate 1 by metal organic chemical vapor deposition (MOCVD). In film forming by the MOCVD method, as known in the art, the substrate 1 is introduced into a film forming device for MOCVD, and gas materials for the respective layers are supplied into the device to form each of the layers on the substrate 1 at a predetermined film forming temperature.

Next, as shown in FIG. 3, the predetermined parts of the n-GaN layer 2, the active layer 3, and the p-GaN layer 4 are removed. This process is performed by a known dry etching method, for example. Specifically, an etching mask with a predetermined width is formed on the p-GaN layer 4, and then the portions uncovered by the mask are subjected to etching, which is continued until the n-GaN layer 2 is partly etched away after the exposure of its surface. Thereafter, the etching mask is removed, and the form shown in FIG. 3 (i.e. one defined by surfaces upright in the thickness direction of the substrate 1) is obtained.

Thereafter, as shown in FIG. 4, part of the active layer 3 is removed so that the active layer 3 has a length smaller than that of the p-GaN layer 4 in the lateral direction of the FIG.. In this process, wet etching is performed to the active layer 3, using KOH solution of 3 mol/l, together with the irradiation of light having a wavelength of 400-430 nm, for example. Preferably, the wavelength of light is set to 408 nm, and the output power is set to about 1 W. Since the active layer 3 amplifies light at wavelength of 400-430 nm, irradiation of light in such a wavelength range puts the layer in an excited state where a chemical reaction is easily induced. On the other hand, at the n-GaN layer 2 and the p-GaN layer 4, no excited state is induced by such light irradiation. Thus, only the active layer 3 can be etched by the use of KOH solution.

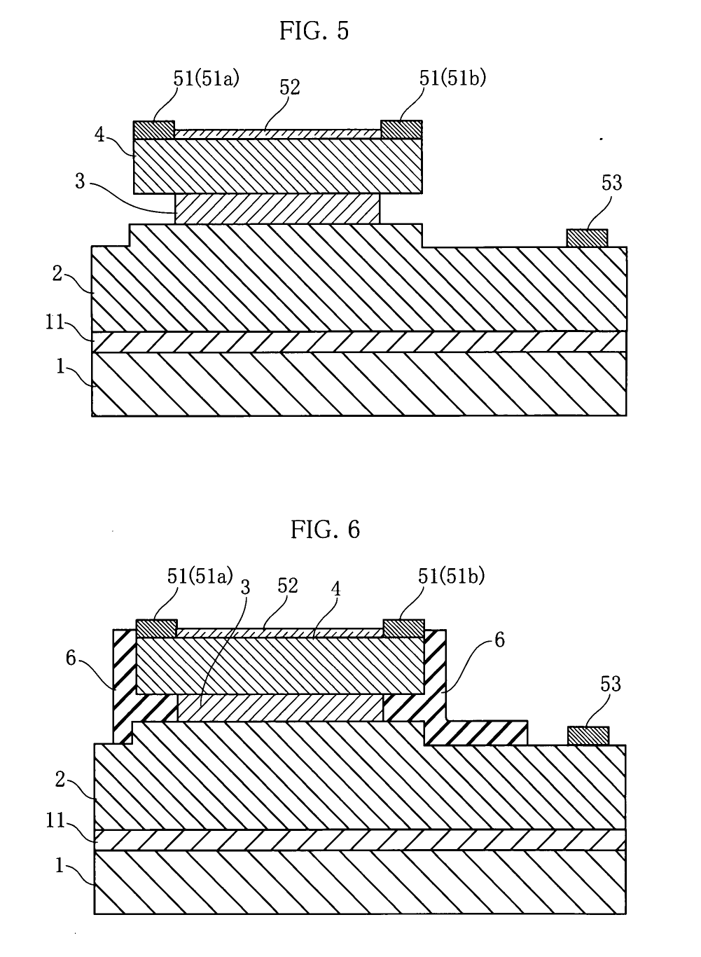

Then, as shown in FIG. 5, the p-electrode 51, the transparent electrode 52 and the n-electrode 53 are provided at predetermined portions by a known method. Finally, as shown in FIG. 6, the insulating layer 6 and then the metal layer 7 are formed, to complete the manufacturing procedure of the semiconductor light emitting element A1.

Next, the functions of the semiconductor light emitting element A1 are described below.

According to the present embodiment, the active layer 3 is not provided immediately below the non-translucent p-electrode 51, and the transparent electrode 52 is provided right above the active layer 3. Thus, most of light emitted from the active layer 3 passes through the transparent electrode 52. In this way, the electrical energy to be used by the semiconductor light emitting element A1 can be reduced.

Further, in the present embodiment, the metal wire is not directly bonded to the p-electrode 51, but to a part of the metal layer 7 (the lower end 7b of the metal layer in FIG. 1). Thus, no force due to the bonding is applied to the portion of the p-GaN layer 4 protruding beyond the active layer 3, which facilitates the bonding step. In this connection, since the insulating layer 6 is partly inserted under the p-GaN layer 4, it is possible to bond the metal wire to the p-electrode 51.

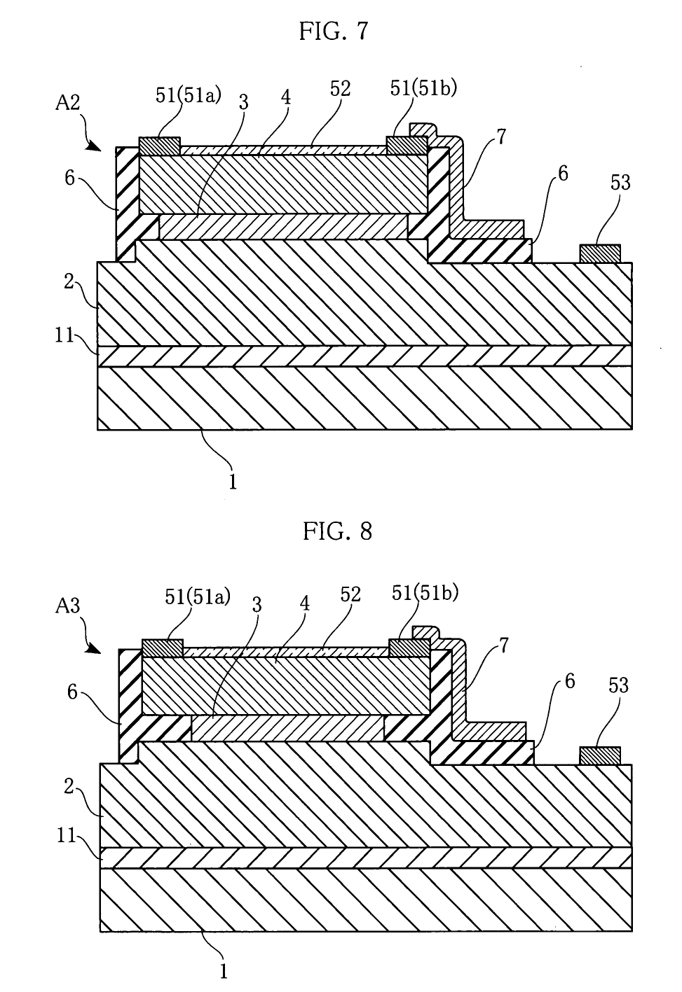

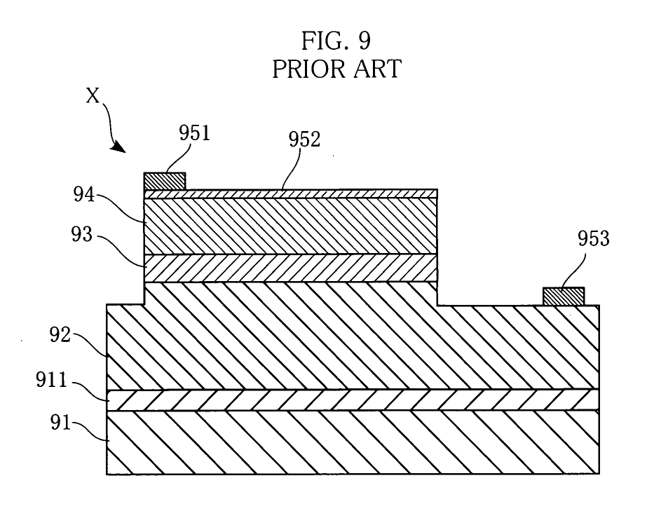

FIG. 7 illustrates a semiconductor light emitting element according to a second embodiment of the present invention. The semiconductor light emitting element A2 is basically the same as the semiconductor light emitting element A1, and only differs in that the active layer 3 has a length longer than that of the semiconductor light emitting element A1. Specifically, in the semiconductor light emitting element A2, as seen in the thickness direction of the substrate 1, the “electrode area” overlaps with only a part of the “residual area” (which is equal to the “semiconductor layer area” minus the “active layer area”). With such a structure, although part of the light emitted from the active layer 3 may be blocked by the p-electrode 51, the p-GaN layer 4 is reliably supported by the active layer 3.

FIG. 8 illustrates a semiconductor light emitting element according to a third embodiment of the present invention. In the semiconductor light emitting element A3, the active layer 3 has a length shorter than that of the semiconductor light emitting element A1, and the other structures are the same as those of the semiconductor light emitting element A1. This feature is taken into the semiconductor light emitting element A3 in light of the fact that the light emitted from the active layer 3 tends to disperse laterally as viewed in the FIG., and it contributes to further reduction in power consumption compared to the semiconductor light emitting element A1.

The semiconductor light emitting element and method of making the same according to the present invention are not limited to the above-described embodiments. For example, in the above embodiments, the p-electrode 51 consists of two elements 51a, 51b. Alternatively, only one element 51b (or 51a) may suffice. Further, the active layer is not limited to the type having an MQW structure. Still further, the semiconductor light emitting element of the present invention may be arranged to emit light of various wavelengths, including blue, green, or white light, for example.

1. A semiconductor light emitting element comprising:
a substrate including an upper surface and a lower surface;
a first nitride semiconductor layer supported by the upper surface of the substrate;
a second nitride semiconductor layer arranged farther from the substrate than the first nitride semiconductor layer is;
an active layer provided between the first and the second nitride semiconductor layers; and
a metal electrode provided on the second nitride semiconductor layer;
wherein as viewed in a thickness direction in which the upper surface and the lower surface of the substrate are spaced from each other, an active layer area provided with the active layer is smaller than a semiconductor layer area provided with the second nitride semiconductor layer, and wherein an electrode area provided with the metal electrode overlaps with at least part of a residual area equal to the semiconductor layer area except the active layer area.

2. The semiconductor light emitting element according to claim 1, wherein the metal electrode is positioned at an end portion of the second nitride semiconductor layer.

3. The semiconductor light emitting element according to claim 1, wherein the electrode area entirely overlaps with the residual area.

4. A method of making a semiconductor light emitting element, the method comprising the steps of:
forming a first nitride semiconductor layer on a substrate;
forming an active layer on the first nitride semiconductor layer;
forming a second nitride semiconductor layer on the active layer;
processing the first nitride semiconductor layer, the second nitride semiconductor layer and the active layer into a form defined by a surface upright in a thickness direction of the substrate; and
subjecting only the active layer to etching for making the active layer narrower than the second nitride semiconductor layer.

5. The method according to claim 4, wherein the etching of the active layer is performed by wet etching comprising irradiation of light having a predetermined wavelength that causes excitation in the active layer but no excitation in the first and the second nitride semiconductor layers.
